(19) United States
(12) Patent Application Publication
(10) Pub. No.: US 2022/0406651 A1
(43) Pub. Date: Dec. 22, 2022

(54) SEMICONDUCTOR DEVICE AND METHOD OF FABRICATING THE SAME

(71) Applicant: Fujian Jinhua Integrated Circuit Co., Ltd., Quanzhou City (CN)

(72) Inventors: Janbo Zhang, Zhangzhou City (CN); Enping Cheng, Quanzhou City (CN); Li-Wei Feng, Tainan City (TW); Yu-Cheng Tung, Kaohsiung City (TW)

(73) Assignee: Fujian Jinhua Integrated Circuit Co., Ltd., Quanzhou City (CN)

(21) Appl. No.: 17/396,775

(22) Filed: Aug. 9, 2021

(30) Foreign Application Priority Data
Jun. 22, 2021 (CN) 202110690524.8
Jun. 22, 2021 (CN) 202121392418.3

(51) Int. Cl. H01L 21/762; H01L 21/8234; H01L 23/00

(52) U.S. Cl. CPC H01L 21/76229; H01L 21/823481; H01L 23/562

(57) ABSTRACT

The present disclosure relates to a semiconductor device and a method of fabricating the same. The semiconductor device includes a substrate, an active structure, and a shallow trench isolation. The active structure is disposed in the substrate, and includes a plurality of first active fragments and a plurality of second active fragments, with the first active fragments and the second active fragments parallel and separately extended along a first direction. A plurality of first openings disposed in the substrate, between two adjacent ones of the first active fragments, and a plurality of second openings disposed in the substrate, between two adjacent ones of the second active fragments, wherein an aperture of the second openings is greater than an aperture of the first openings. The shallow trench isolation is disposed in the substrate to fill in the first openings and the second openings, and to surround the active structure.

### BACKGROUND OF THE INVENTION

### 1. Field of the Invention

The present disclosure generally relates to a semiconductor device and a method of fabricating the same, and more particularly, to a semiconductor device having active regions and shallow trench isolations, and a method of fabricating the same.

### 2. Description of the Prior Art

With the miniaturization of semiconductor devices and the complexity of integrated circuits, the size of elements is continuously shrinking and the structure is constantly changing. Therefore, maintaining the performance of small-sized semiconductor elements is the standard purpose of the present industry. In the semiconductor fabricating process, most of the active regions are defined on the substrate as a bass element, and then, the required elements are further formed on the active regions. Generally, the active regions are plural patterns formed within the substrate through the photolithography and etching processes. However, due to the sized-shrinking requirements, the width of the active regions has been gradually reduced, and the pitch between the active regions has also been gradually reduced thereby, so that, the fabricating process of active regions encounters plenty limitations and challenges that fails to meet the practical product requirements.

### SUMMARY OF THE INVENTION

One of the objectives of the present disclosure provides a semiconductor device and a fabricating method thereof, in which the active structure includes plural active fragments in various lengths, and the active fragments may directly connect to a peripheral active region. Accordingly, the active fragments may effectively improve the stresses around the semiconductor device, thereby avoiding the semiconductor structural collapse or damages. Then, the semiconductor device of the present disclosure may therefore obtain better functions and device performance.

To achieve the purpose described above, one embodiment of the present disclosure provides a semiconductor device including a substrate, an active structure and a shallow trench isolation. The active structure is disposed within the substrate and includes a plurality of first active fragments and a plurality of second active fragments, with the first active fragments and the second active fragments being parallel and separately extended along a first direction, wherein the first fragments are alternately arranged in a second direction which is perpendicular to the first direction, and two adjacent ones of the second active fragments have aligned end faces in the second direction. The shallow trench isolation is disposed within the substrate to surround the active structure, and the shallow trench isolation includes a plurality of first isolating regions and a plurality of second isolating regions. The first isolating regions are disposed between two adjacent ones of the first active fragments, the second isolating regions are disposed between two adjacent ones of the two active fragments, and a maximum width of the second isolating regions is greater than a maximum width of the first isolating regions.

To achieve the purpose described above, one embodiment of the present disclosure provides a method of fabricating the semiconductor device including the following steps. Firstly, a substrate is provided, a plurality of active region units is formed in the substrate, with the active units being parallel and separately extended along a first direction. Next, a plurality of first openings and a plurality of second openings are formed in the substrate, to cutoff the active region units into a plurality of first active fragments, a plurality of second active fragments, and a plurality of third active fragments, thereby forming an active structure, wherein an aperture of the second openings is greater than an aperture of the first openings in a second direction which is perpendicular to the first direction, and the first fragments are alternately arranged in the second direction, and two adjacent ones of the second active fragments have aligned end faces in the second direction. Then, a shallow trench isolation is formed in the substrate to surround the active structure, wherein the shallow trench isolation is filled in the first openings and the second openings.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 2 are schematic diagrams illustrating a semiconductor device according to a first preferable embodiment in the present disclosure, wherein:

FIG. 1 shows a top view of an active structure of a semiconductor device; and

FIG. 2 shows a cross-sectional view of a semiconductor device taken along a cross-line A-A′ in FIG. 1.

FIG. 3 to FIG. 5 are schematic diagrams illustrating a fabricating method of a semiconductor device according to a preferable embodiment in the present disclosure, wherein:

FIG. 3 shows a top view illustrating a semiconductor structure after forming a shallow trench and active region units;

FIG. 4 shows a cross-sectional view taken along a cross-line A-A′ in FIG. 3; and

FIG. 5 shows a top view illustrating a semiconductor structure after forming first openings and second openings.

FIG. 6 is a schematic diagram illustrating a semiconductor device according to a second preferable embodiment in the present disclosure.

FIG. 7 is a schematic diagram illustrating a semiconductor device according to a third preferable embodiment in the present disclosure.

### DETAILED DESCRIPTION

To provide a better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

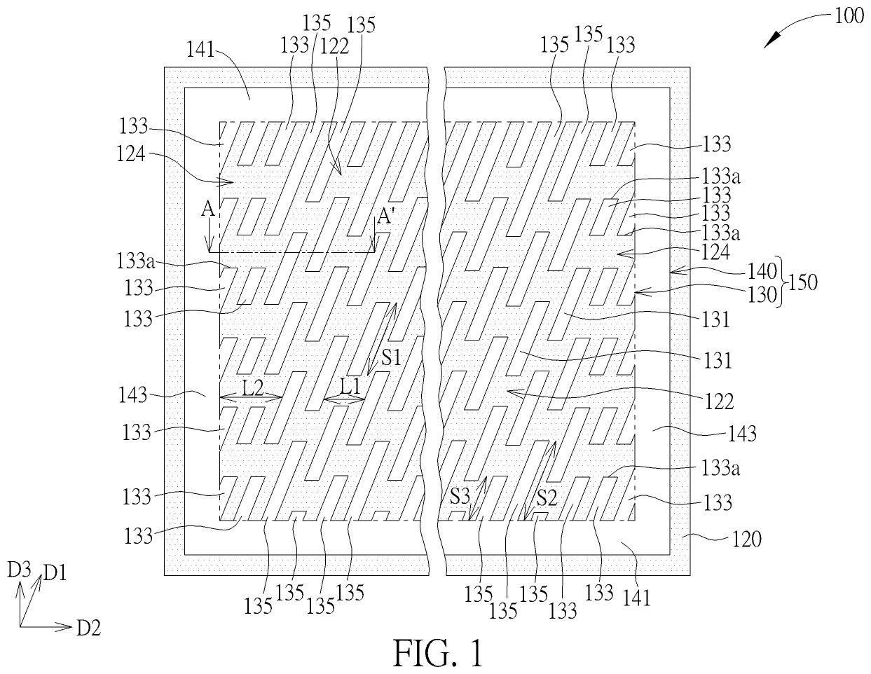

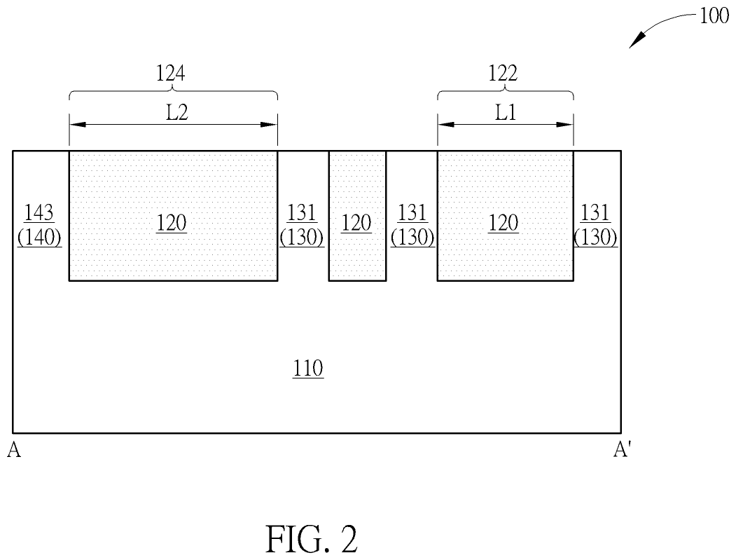

Please refer to FIGS. 1-2, which illustrate schematic diagrams of a semiconductor device 100 according to the first preferable embodiment in the present disclosure, with FIG. 1 illustrating a top view of the semiconductor device 100, and with FIG. 2 illustrating a cross-sectional view of the semiconductor device 100. The semiconductor device 100 includes a substrate 110, for example a silicon substrate, a silicon containing substrate (such as SiC or SiGe), or a silicon-on-insulator (SOI) substrate, and at least one shallow trench isolation (STI) 120 is disposed in the substrate 110, to define an active structure 150 in the substrate 110. That is, the shallow trench isolation 120 is disposed around the active structure 150. The active structure 150 further includes a first active region 130 and a second active region 140, and the second active region 140 disposed outside the periphery of the first active region 130, to serve as a peripheral active region. In one embodiment, the first active region 130 is for example disposed at an area being highly integrity in the semiconductor device 100, such as an active area (AA) region or a memory cell region, and the second active region 140 is for example disposed at an area being lower integrity in the semiconductor device 100, such as a peripheral region, but is not limited thereto.

As shown in FIG. 1 and FIG. 2, the first active region 130 further includes a plurality of first active fragments 131, a plurality of second active fragments 133 and a plurality of third active fragments 135, being parallel extended along a same direction (such as a first direction D1). The first direction D1 is for example not perpendicular to the x-direction (such as a second direction D2) or the y-direction (such as a third direction D3). Precisely speaking, the first active fragments 131, the second active fragments 133, and the third active fragments 135 are separately disposed within the substrate 110, and the first active fragments 131, the second active fragments 133 and the third active fragments 135 are sequentially arranged along the first direction D1 into plural columns, thereby presenting a particular arrangement, such as an array arrangement, but not limited thereto. It is noted that the shallow trench isolation 120 further includes a plurality of first isolating regions 122 and a plurality of second isolating regions 124, two adjacent ones of the first active fragments 131 are spaced apart by the first isolating region 122, and each of the first active fragment 131 has the same length in the first direction D1, being the length S1. The third active fragments 135 are disposed at two opposite sides (for example the top side and the bottom side of FIG. 1) of all of the first active fragments 131 in the third direction D3, to directly contact the second active region 140. The adjacent ones of the first active fragments 131 and the third active fragments 135 are also spaced apart by the first isolating region 122, and the third active fragments 135 may have different lengths (for example the lengths S2, S3) respectively in the first direction D1, which is different from the length S1. Also, the second active fragments 133 are disposed at two opposite sides of all of the first active fragments 131 and the third active fragments 135 in the second direction D2, to partially contact the second active region 140, wherein two adjacent ones of the second active fragments are spaced apart by the second isolating regions 124, to obtain a length (not shown in the drawings) being smaller than the length S1 of the first active fragments 131 in the first direction D1. The second isolating regions 124 have a maximum width L2 in the second direction D2, and the maximum width L2 is greater than a maximum width L1 of the first isolating regions 122, so that, the adjacent ones of the second active fragments 133 in the second direction D2 may have aligned end faces 133a which are in alignment with each other, as shown in FIG. 1.

On the other hand, the second isolating regions 124 are disposed at two opposite sides (for example the left side and the right side in FIG. 1) of all of the first isolating regions 122 in the second direction D2, and the second isolating regions 124 and the first isolating regions 122 are sequentially arranged along the third direction D3 into plural columns, with the second isolating regions 124 or the first isolating regions 122 arranged within each column being in alignment with each other, with the second isolating regions 124 or the first isolating regions 122 arranged within two adjacent columns being in misalignment with each other in the second direction D2, thereby also presenting an array arrangement as a whole, but not limited thereto.

The second active region 140 further includes at least one first edge 141 extended along the second direction D2, and at least one second edge 143 extended along the third direction D3, such that, the whole second active region 140 may perform like a rectangular frame to directly in contact with the third active fragments 135 and a portion of the second active fragments 133. That is, all of the third active fragments 135 may further connect to the first edge 141 of the second active region 140 directly, and the portion of the second active fragments 133 may optionally connect to the first edge 141, the second edge 143, or simultaneously connect to the first edge 141 and the second edge 143 of the second active region 140 directly, with another portion of the second active fragments 133 being not connected with the first edge 141 and/or the second edge 143 of the second active region 140, as shown in FIG. 1. With these arrangements, the second active region 140 is allowable to uniformly disperse the stresses suffered from the first active region 130 and the shallow trench isolation 120, thereby obtaining a further reliable structure. People in the art should fully realize that the practical disposing number of the first edge or the second edge may be further adjustable due to practical product requirements, or the second active region is not limited to be the aforementioned rectangular frame, for example, further edges may be additionally disposed to make the second active region to perform like various shapes.

Through these arrangements, the semiconductor device 100 of the first preferable embodiment of the present disclosure is provided, in which the second active fragments 133 in different lengths are disposed at the right side and the left side of the first active fragments 131, and the third active fragments 135 in different lengths are disposed at the top side and the bottom side of the first active fragments 131, with a portion of the second active fragments 133 further in connection with at least one edge (including the first edge 141, the second edge 143, or the first edge 141 and the second edge 143) of the second active region 140, and with the third active fragments 135 further in connection with the first edge 141 of the second active region 140. In this way, the second active fragments 133 and the third active fragments 135 enable to provide different extension lengths to stabilize and to strengthen the structure of the peripheral active region, namely the second active region 140, disposed around the first active fragments 131, thereby improving the peripheral stresses of the semiconductor device 100, and avoiding the collapse or cracking of the surrounding structure. After that, the semiconductor device 100 may be further used on fabricating other semiconductor active devices, such as a transistor device or a memory device, to significantly improve the performance of the subsequently formed devices.

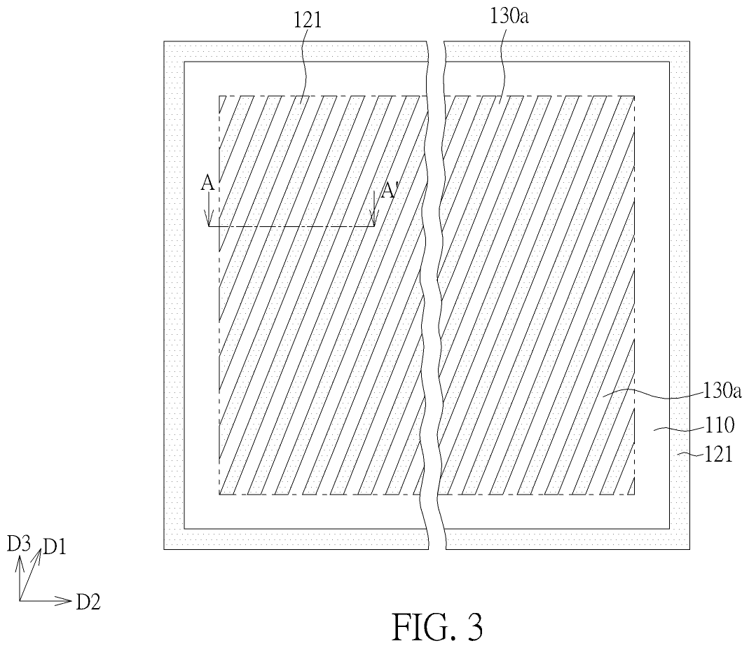

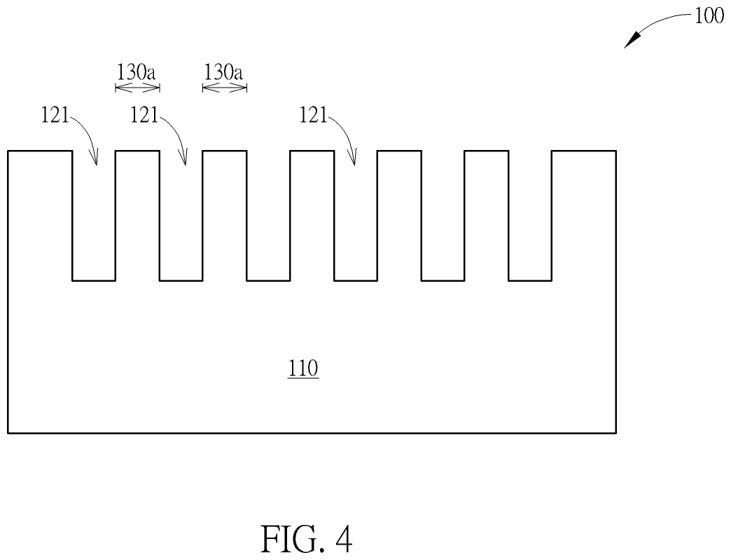

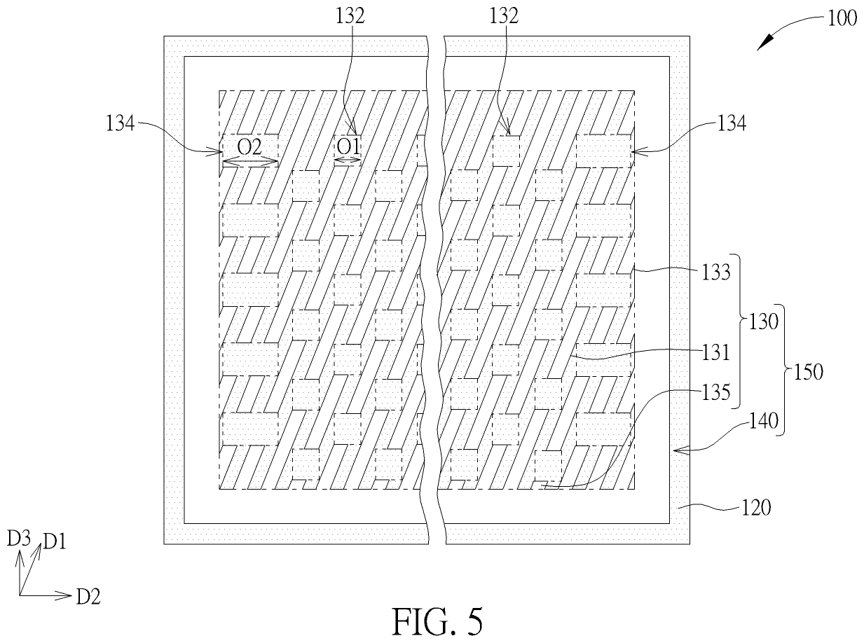

In order to enable one of ordinary skill in the art to implement the present disclosure, a method of fabricating a semiconductor device 100 of the present disclosure is further described below. Please refer to FIG. 3 to FIG. 5, which respectively illustrate a fabricating process of a semiconductor device 100 according to a preferable embodiment in the present disclosure, wherein the formation of the active structure 150 is but not limited to be accomplished by a following patterning process. Firstly, a mask layer (not shown in the drawings) may be formed on the substrate 110, with the mask layer including patterns for defining a plurality of active region units 130a and with a portion of the substrate 110 being exposed form the mask layer, and an etching process is performed by using the mask layer, to remove the portion of the substrate 110 and to form at least one shallow trench 121, and to simultaneously define the active region units 130a in the substrate 110. The active region units 130a are parallel and separately extended along the first direction D1, as shown in FIG. 3 and FIG. 4. Then, as shown in FIG. 5, another mask layer (not shown in the drawings) is formed on the substrate 110, with the another mask layer including patterns for defining the first openings 132 and the second openings 134, to expose a portion of the active region units 130a, and another etching process is performed by using the another mask layer, to remove the portion of the active region units 130a, thereby forming the first openings 132 and the second openings 134 which are marked by dotted rectangular boxes in FIG. 5. Meanwhile, the active region units 130a are cutoff by the first openings 132 and the second openings 134, to form the first active fragments 131, the second active fragments 133, and the third active fragments 135. Precisely speaking, the second openings 134 have a relative greater aperture O2 in the second direction D2 which is greater than the aperture O1 of the first openings 132 in the second direction. Also, the second openings 134 and the first openings 132 are sequentially arranged along the third direction D3 into plural columns, with the second openings 134 and the first openings 132 arranged within each column being in alignment with each other, with the second openings 134 and the first openings arranged within two adjacent columns being in misalignment with each other in the second direction D2, thereby also presenting an array arrangement as a whole, but not limited thereto. Next,

the second isolating regions 124 are disposed at two opposite sides (for example the left side and the right side in FIG. 1) of all of the first isolating regions 122 in the second direction D2, and the second isolating regions 124 and the first isolating regions 122 are sequentially arranged along the third direction D3 into plural columns, with the second isolating regions 124 or the first isolating regions 122 arranged within each column being in alignment with each other, with the second isolating regions 124 or the first isolating regions 122 arranged within two adjacent columns being in misalignment with each other in the second direction D2, thereby also presenting an array arrangement as a whole, but not limited thereto. Following these, an insulating material (not shown in the drawings) for example including silicon oxide (SiOₓ), silicon nitride (SiN) or silicon oxiynitride (SiON) is formed to fill in the shallow trench 121, the first openings 132, and the second openings 134, to form the shallow trench isolation 120 having a top surface being coplanar with the top surface of the substrate 110. The insulating material filled in the first openings 132 and the second openings respectively form the first isolating regions 122 and the second isolating regions 124.

After forming the first active region 130, the second active region 140 may be next formed in the substrate 110. In the present embodiment, the formation of the second active region 140 may also be accomplished by the patterning process of the substrate 110, and which may optionally be carried out together with the patterning process of the first active region 130. That is, in the present embodiment, the same or different mask layer(s) may be used to either simultaneously define or separately define the patterns of the first active region 130 and the second active region 140, followed by etching the substrate 110 and filling in the insulating material. Then, the first active region 130 and the second active region 140 may include the same material, namely the material of the substrate 110, and also, the first edge 141 and the second edge 143 of the second active region 140, and the third active fragments 135 and the second active fragments 133 which are connected with the first edge 141 and the second edges 143 may be monolithic, as shown in FIG. 5. In this situation, the second active region 140 may obtain a relative stable, strengthened structure to protect the first active fragments 131 disposed at the inner side of the second active region 140. Then, the structural collapse or damage of the first active region 130 may be successfully avoided. However, people in the art should fully realize that the formation of the second active region is not limited to be accomplished through the aforementioned process, and which may also be formed through other processes, for example being carried out separately from the formation of the first active region. As an example, in one embodiment, the fabricating process of the second active region may be performed before the fabricating process of the first active region, in which, the second active region may be formed firstly through the patterning process of the substrate, and the first active region is then formed by performing an epitaxial growth process (not shown in the drawings). Accordingly, the topmost surfaces of the second active region and first active region may not be leveled with each other. Otherwise, in another embodiment, the fabricating process of the second active region may also be performed after the fabricating process of the first active region, in which, the first active region is firstly formed through the patterning process of the substrate, and the second active region is then formed through a deposition process. Accordingly, the second active region and the first active region may include different materials, for example, the second active region may include polysilicon or a dielectric material which is different from that of the substrate.

People in the art should fully realize that the semiconductor device and the fabricating method thereof are not be limited to the aforementioned embodiment and may include other examples or may be achieved through other strategies to meet practical product requirements. For example, in one embodiment, the etching conditions may be further adjusted during the patterning process of first active region 130 and/or the second active region 140, thereby forming an active structure with rounding corners (not shown in the drawings), but not limited thereto. The following description will detail the different embodiments of the semiconductor device and the fabricating method thereof in the present disclosure. To simplify the description, the following description will detail the dissimilarities among the different embodiments and the identical features will not be redundantly described. In order to compare the differences between the embodiments easily, the identical components in each of the following embodiments are marked with identical symbols.

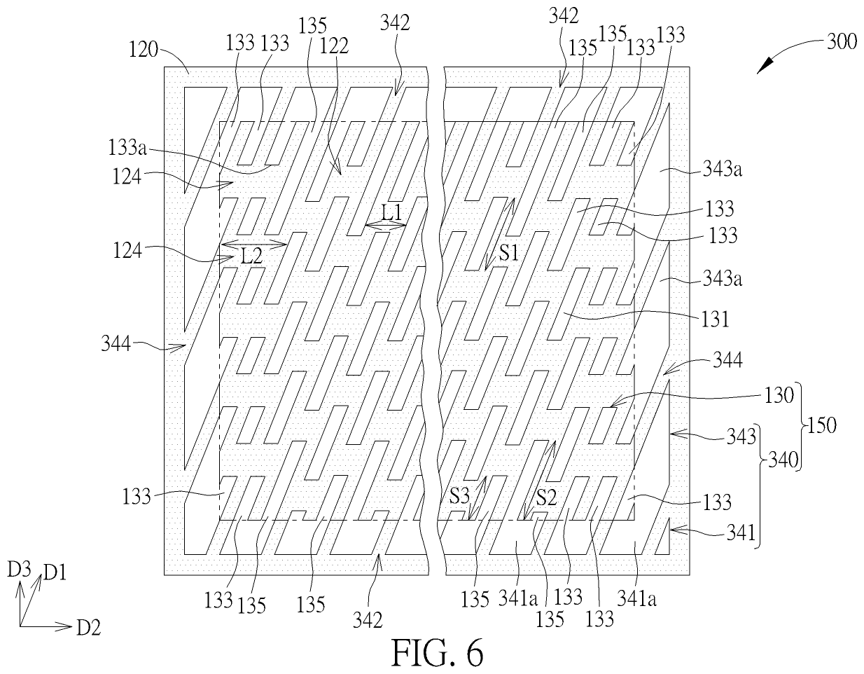

Please refer to FIG. 6, which illustrates a semiconductor device 300 according to the second preferable embodiment of the present disclosure. In the present embodiment, the structure of the semiconductor device 300 is substantially the same as those of the aforementioned first preferable embodiment, including the substrate 110, the active structure 150 (for example including the first active region 130 and the second active region 340), and the shallow trench isolation 120 (for example including the first isolating regions 122 and the second isolating region s 124), and which may not be redundantly described hereinafter. The difference between the present embodiment and the aforementioned embodiment is in that a plurality of openings 342, 344 is additionally disposed within the substrate 110, to cutoff the first edge 341 and the second edge 343 of the second active region 340 into a plurality of fragments 341a, 343a.

Precisely speaking, each of the fragments 341a of the first edge 341 is separately by the shallow trench isolation 120, and which is directly in contact with two adjacent ones of the third active fragments 135, two adjacent ones of the second active fragments 133, or adjacent ones of the third active fragments 135 and the second active fragments 133. While each of the fragments 341a is connected with either two adjacent ones of the third active fragments 135, or adjacent ones of the third active fragments 135 and the second active fragments 133, the two adjacent ones of the third active fragments 135 or the adjacent ones of the third active fragments 135 and the second active fragments 133 may have different lengths in the first direction D1, respectively. While each of the fragments 341a is connected with two adjacent ones of the second active fragments 133, the two adjacent ones of the second active fragments 133 may have the same length in the first direction D1, as shown in FIG. 6. On the other hand, each of the fragments 343a of the second edge 343 is also separately by the shallow trench isolation 120, to directly contact at least one second active fragments 133, preferably being connected to two adjacent ones of the second active fragments 133 in the third direction D3.

With these arrangements, the semiconductor device 300 of the second preferable embodiment of the present disclosure is provided, in which the second active fragments 133 and the third active fragments 135 enable to provide different extension lengths to stabilize and to strengthen the structure of the second active region 340, to improve the peripheral stresses of the semiconductor device 300, and to avoid the collapse or cracking of the surrounding structure. Furthermore, the semiconductor device 300 of the present embodiment further includes the openings 342, 344 disposed on the second active region 340, to further disperse the stresses on each edge (including the first edge 341 and the second edge 343) of the second active region 340, so as to obtain a more reliable structure. In this way, the device performance formed subsequently on the semiconductor device 300 may also be improved thereby.

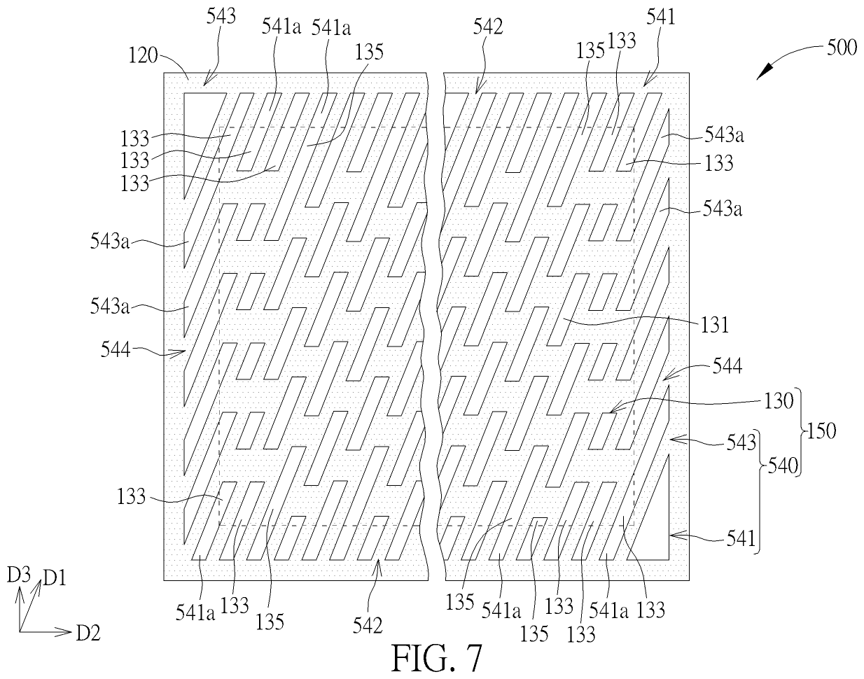

Please refer to FIG. 7, which illustrates a semiconductor device 500 according to the third preferable embodiment of the present disclosure. In the present embodiment, the structure of the semiconductor device 500 is substantially the same as those of the aforementioned first preferable embodiment, including the substrate 110, the active structure 150 (for example including the first active region 130 and the second active region 540), and the shallow trench isolation 120 (including the first isolating regions 122 and the second isolating regions 124), and which may not be redundantly described hereinafter. The difference between the present embodiment and the aforementioned embodiment is in that a plurality of openings 542, 544 is additionally disposed within the substrate 110, to cutoff the first edge 541 and the second edge 543 of the second active region 540 into a plurality of fragments 541a, 543a.

Precisely speaking, each of the fragments 541a of the first edge 541 is separately by the shallow trench isolation 120 in the second direction D2 to directly contact each of the third active fragments 135 or the second active fragments 133. Likewise, each of the fragments 543a of the second edge 543 is also separately by the shallow trench isolation 120, to directly contact a portion of the second active fragments 133, as shown in FIG. 7. With these arrangements, the semiconductor device 500 of the second preferable embodiment of the present disclosure is provided, in which the second active fragments 133 and the third active fragments 135 also enable to provide different extension lengths to stabilize and to strengthen the structure of the second active region 540, to improve the peripheral stresses of the semiconductor device 500, and to avoid the collapse or cracking of the surrounding structure. Furthermore, the semiconductor device 500 of the present embodiment further includes the openings 542, 544 disposed on the second active region 540, to further disperse the stresses on each edge (including the first edge 541 and the second edge 543) of the second active region 540, so as to obtain a more reliable structure. In this way, the device performance formed subsequently on the semiconductor device 300 may also be improved thereby.

Overall speaking, according to the semiconductor device in the present disclosure, the active fragments with various lengths are respectively disposed at the left and right sides, and the top and bottom sides of the active fragments disposed within the AA region or the memory cell region, with the active fragments with various lengths further connecting to at least one edge of the active region which is disposed within the periphery region. Through these arrangements, the active fragments with various lengths may enable to provide various extension lengths to stabilize and to strengthen the structure of the peripheral active region, thereby improving the stresses around the semiconductor device, and avoiding the collapse or cracking of the peripheral structure. In addition, the at least one edge of the active region may further include a plurality of separate fragments to further disperse the stresses borne by the at least one edge. In this way, the semiconductor device of the present disclosure may be further used on fabricating other semiconductor active devices, such as a memory device or a transistor device, so as to achieve an improved performance to the device formed subsequently.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising;
a substrate;
an active structure, disposed within the substrate, the active structure comprising a plurality of first active fragments and a plurality of second active fragments, the first active fragments and the second active fragments being parallel and separately extended along a first direction, wherein the first fragments are alternately arranged in a second direction which is perpendicular to the first direction, and two adjacent ones of the second active fragments have aligned end faces in the second direction; and
a shallow trench isolation, disposed within the substrate to surround the active structure, the shallow trench isolation comprising a plurality of first isolating regions and a plurality of second isolating regions, wherein the first isolating regions are disposed between two adjacent ones of the first active fragments, the second isolating regions are disposed between two adjacent ones of the two active fragments, and a maximum width of the second isolating regions is greater than a maximum width of the first isolating regions.

2. The semiconductor device according to claim 1, wherein the first active fragments have a same first length in the first direction and the first length is greater than a length of the second active fragments in the first direction.

3. The semiconductor device according to claim 1, wherein the second isolating regions are disposed at two opposite side of the first isolating regions, and each of the second isolating regions are in alignment with each other in a third direction which is perpendicular to the second direction.

4. The semiconductor device according to claim 3, wherein the active structure further comprises an active region, the active region surrounds the first active fragments and the second active fragments and directly contacts a portion of the second active fragments.

5. The semiconductor device according to claim 4, wherein the active region comprises at least one first edge extending along the second direction, and at least one second edge extending along the third direction.

6. The semiconductor device according to claim 4, wherein the active structure further comprises a plurality of third active fragments parallel and separately extending along the first direction, and all of the third active fragments directly contacts the active region.

7. The semiconductor device according to claim 6, wherein the third active fragments have different lengths respectively in the first direction.

8. The semiconductor device according to claim 6, wherein the third active fragments have a length in the first direction, and the length of the third active fragments is different from the first length.

9. The semiconductor device according to claim 6, wherein the active region comprises a plurality of fragments, each of the fragments are separated and directly contacts two adjacent ones of the third active fragments, two adjacent ones of the second active fragments, or adjacent ones of the third active fragments and the second active fragments.

10. The semiconductor device according to claim 9, wherein the two adjacent ones of the third active fragments have different lengths in the first direction.

11. A method of forming a semiconductor device, comprising;
providing a substrate;
forming a plurality of active region units in the substrate, the active units being parallel and separately extended along a first direction;
forming a plurality of first openings and a plurality of second openings in the substrate, to cutoff the active region units into a plurality of first active fragments, a plurality of second active fragments, and a plurality of third active fragments, and to form an active structure, wherein an aperture of the second openings is greater than an aperture of the first openings in a second direction which is perpendicular to the first direction, and the first fragments are alternately arranged in the second direction, and two adjacent ones of the second active fragments have aligned end faces in the second direction; and
forming a shallow trench isolation in the substrate, to surround the active structure, wherein the shallow trench isolation is filled in the first openings and the second openings to form a plurality of first isolating regions and a plurality of second isolating regions.

12. The method of fabricating the semiconductor device according to claim 11, wherein the first active fragments have a same first length in the first direction and the first length is greater than a length of the second active fragments in the first direction.

13. The method of fabricating the semiconductor device according to claim 11, wherein the second openings are formed at two opposite sides of the first openings, and each of the second openings are in alignment with each other in a third direction which is perpendicular to the second direction.

14. The method of fabricating the semiconductor device according to claim 11, wherein the third active fragments have different lengths respectively in the first direction and the lengths of the third active fragments are different from the first length.

15. The method of fabricating the semiconductor device according to claim 13, further comprising:
forming an active region in the substrate, the active region surrounding the first active fragments, the second active fragments and the third active fragments, wherein the active region directly contacts the third active fragments and a portion of the second active fragments.

16. The method of fabricating the semiconductor device according to claim 15, wherein the active region comprises at least one first edge extending along the second direction, and at least one second edge extending along the third direction.

17. The method of fabricating the semiconductor device according to claim 16, wherein the active region further comprises a plurality of fragments, each of the fragments are separated and directly contacts two adjacent ones of the third active fragments, two adjacent ones of the second active fragments, or adjacent ones of the third active fragments and the second active fragments.

18. The method of fabricating the semiconductor device according to claim 17, wherein the two adjacent ones of the third active fragments have different lengths in the first direction.
